(19) United States
(12) Patent Application Publication
(10) Pub. No.: US 2023/0178616 A1
(43) Pub. Date: Jun. 8, 2023

(54) SEMICONDUCTOR DEVICE AND METHOD FOR MANUFACTURING THE SAME

(71) Applicant: DYNAX SEMICONDUCTOR, INC., Kunshan (CN)

(72) Inventors: Naiqian ZHANG, Kunshan (CN); Yi PEI, Kunshan (CN)

(21) Appl. No.: 17/912,796

(22) PCT Filed: Mar. 24, 2021
(86) PCT No.: PCT/CN2021/082675

§ 371 Date: Sep. 19, 2022

(30) Foreign Application Priority Data
Mar. 25, 2020 (CN) 202010218154.3

(51) Int. Cl. H01L 29/423; H01L 29/40; H01L 29/417

(52) U.S. Cl. CPC H01L 29/42376; H01L 29/4238; H01L 29/401; H01L 29/41775

(57) ABSTRACT

Embodiments of the present disclosure disclose a semiconductor device and a method for manufacturing the same. The semiconductor device includes an active region and a passive region, the semiconductor device further includes a substrate, a multilayer semiconductor layer, and a source, a gate and a drain, the gate being located between the source and the drain, wherein, in a first direction, the gate includes, in turn, a first end portion, an intermediate portion and a second end portion, the intermediate portion, the source and the drain all being located in the active region, and the first end portion and/or the second end portion extending into the passive region, and in a second direction, an extension width of a portion at least located in the passive region of the first end portion and/or the second end portion is greater than an extension width of the intermediate portion.

### CROSS REFERENCE TO RELATED APPLICATIONS

This patent application is a National Stage Entry of PCT/CN2021/082675 filed on Mar. 24, 2021, which claims the benefit and priority of Chinese Patent Application No. 202010218154.3 filed on Mar. 25, 2020, the disclosures of which are incorporated by reference herein in their entirety as part of the present application.

### BACKGROUND

Embodiments of the present disclosure relate to the field of semiconductor technologies, and particularly to a semiconductor device and a method for manufacturing the same.

Since the semiconductor material Gallium Nitride (GaN) has characteristics such as great forbidden band width, high electron mobility, high breakdown field strength, good thermal conductivity etc., and has a strong spontaneous and piezoelectric polarization effect, compared with the first generation semiconductor material and the second generation semiconductor material, it is more suitable for manufacturing high frequency, high voltage and high temperature resistant high power electronic devices, particularly in the field of RF and power supply.

At present, 5G communication requires high bandwidth and high frequency for semiconductor devices, and the gate structure design and process flow are closely related to the frequency characteristics of semiconductor devices, and the size of the gate directly affects the operating frequency of semiconductor devices. Therefore, the gate design is particularly important in the design and manufacture of semiconductor devices, and plays a key role in the reliability and stability of the working performance of semiconductor devices.

Therefore, it has become an urgent problem how to further improve the reliability of gate of semiconductor, realize the gate design with stable performance of semiconductor devices, and use it to achieve large-scale commercial production manufacture.

### BRIEF DESCRIPTION

On that account, embodiments of the present disclosure provide a semiconductor device and a method for manufacturing the same, to provide a semiconductor device with high gate reliability and stable semiconductor device performance, which can be used in the fields of RF microwave, power electronics, etc.

In a first aspect, an embodiment of the present disclosure provides a semiconductor device, including an active region and a passive region surrounding the active region. The semiconductor device further includes a substrate, a multilayer semiconductor layer located on one side of the substrate, and a source, a gate and a drain located on one side of the multilayer semiconductor layer away from the substrate, the gate being located between the source and the drain, wherein, in a first direction, the gate includes, in turn, a first end portion, an intermediate portion and a second end portion, the intermediate portion, the source and the drain all being located in the active region, the first end portion and/or the second end portion extending into the passive region, and the first direction is parallel to the extension direction of the source, the gate and the drain, and in a second direction, an extension width of a portion at least located in the passive region of the first end portion and/or the second end portion is greater than an extension width of the intermediate portion, and the second direction is parallel to the direction in which the source points to the drain.

The first end portion and/or the second end portion extending into the passive region may be bent toward one side of the source.

An edge outline of the first end portion and/or the second end portion extending into the passive region on at least one side close to the source or the drain may include a first curve, and a circle center corresponding to an arc in which any two points of the first curve are located is on the same side of the first curve.

The first curve may include a first point and a second point, the second point being located on one side of the first point close to the passive region, and a curvature radius corresponding to the second point is greater than a curvature radius corresponding to the first point.

The first curve may include a first curve start point and a first curve end point, the source may include a first source corner and a second source corner located on one side close to the gate, and the first source corner and/or the second source corner are/is a chamfer/chamfers, or the drain may include a first drain corner and a second drain corner located on one side close to the gate, and the first drain corner and/or the second drain corner are/is a chamfer/chamfers, the chamfer may include a chamfer start point and a chamfer end point, and the first curve start point is located at the same position or further away from the intermediate portion in the first direction compared to the chamfer start point, and the first curve end point is located at the same position or further away from the gate in the second direction compared to the chamfer end point.

A start position of at least one of the first end portion and the second end portion may be located at the same position or further away from the intermediate portion in the first direction compared to the chamfer start point.

The edge outline may further include a second curve smoothly connected to the first curve, the second curve being located on one side of the first curve close to the passive region, and the circle centers corresponding to the arcs where any two points in the first curve and any two points in the second curve are located are located on different sides of the edge outline, respectively.

A circle center corresponding to an arc in which any two points of the first curve are located is on the same side of the first curve, and a curvature radius corresponding to any point in the first curve is greater than an extension width of the intermediate portion in the second direction, and wherein, a curvature radius corresponding to any point in the first curve is R, the extension width of the intermediate portion in the second direction is D, and 1.5*D≤R≤20*D.

The semiconductor device may further include a field plate structure located on one side of the gate away from the multilayer semiconductor layer, and a plate capacitor is formed by the field plate structure and the gate.

The shape of the first end portion and/or the second end portion extending into the passive region may include at least one of a hammerhead shape, a circular shape, a semi-circular shape, a bulb shape, a rectangle shape, and an L shape.

The extension width of the first end portion and/or the second end portion extending into the passive region is L, and the extension width of the intermediate portion is D, where 1.2*D≤L≤30*D.

In a second aspect, an embodiment of the present disclosure provides a method of manufacturing the above-mentioned semiconductor device, including providing a substrate, forming a multilayer semiconductor layer on one side of the substrate, and forming a source, a gate and a drain on one side of the multilayer semiconductor layer away from the substrate, the gate being located between the source and the drain, wherein, in a first direction, the gate includes, in turn, a first end portion, an intermediate portion and a second end portion, the intermediate portion, the source and the drain all being located in the active region, the first end portion and/or the second end portion extending into the passive region, and the first direction is parallel to the extension direction of the source, the gate and the drain, and in a second direction, an extension width of a portion at least located in the passive region of the first end portion and/or the second end portion is greater than an extension width of the intermediate portion, and the second direction is parallel to the direction in which the source points to the drain.

In the semiconductor device and method of manufacturing the same provided in embodiments of the present disclosure, a first end portion and/or a second end portion of the gate extending into the passive region are/is provided, and in the direction of the source pointing to the drain, the extension width of the portion of the first end portion and/or the second end portion at least located in the passive region is greater than the extension width of the intermediate portion. In this way, the first end portion and/or the second end portion located at least in the passive region has a greater extension width, and the first end portion and/or the second end portion of the gate having the greater extension width facilitates the penetration of the developer from at least one end portion to the intermediate portion, which can correct the distortion of the gate shape corresponding to the corner position at two ends of the source and drain due to light diffraction, significantly reduce the development difficulty, ensure that the gate shape corresponding to the corner position at two ends of the source and drain is the same or of slight difference with the shape of the intermediate portion, and ensure a stable gate structure and stable performance, which can further prevent distortion of the gate shape from affecting the power and frequency of the semiconductor device and ensure the performance of the semiconductor device is stable.

### BRIEF DESCRIPTION OF THE DRAWINGS

FIG. 1 is a structure schematic diagram of a semiconductor device in the prior art;

FIG. 2 is a structure schematic diagram of a semiconductor device provided by an embodiment of the present disclosure;

FIG. 3 is a top view structure schematic diagram of a semiconductor device provided by an embodiment of the present disclosure;

FIG. 4 is an enlarged structure schematic diagram of the cc region in FIG. 3;

FIG. 5 is a top view structure schematic diagram of a gate provided by an embodiment of the present disclosure;

FIG. 6 is a top view structure schematic diagram of another gate provided by an embodiment of the present disclosure;

FIG. 7 is a cross-sectional structure schematic diagram of a semiconductor device provided by an embodiment of the present disclosure; and

FIG. 8 is a schematic flow diagram of a method of manufacturing a semiconductor device provided by an embodiment of the present disclosure.

### DETAILED DESCRIPTION

Hereinafter, the present disclosure is further described in detail in conjunction with the accompanying drawings and the embodiments. It may be appreciated that the specific embodiments described herein are merely used to explain the present disclosure, but not used to limit the present disclosure. Furthermore, it should be noted that only the components related to the present disclosure, instead of all components, are shown in the accompanying drawings, for ease of description.

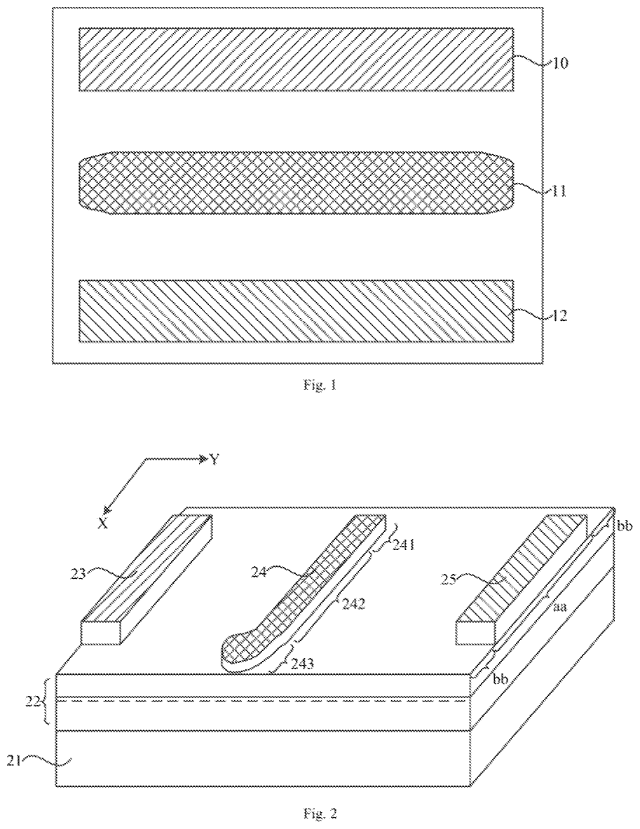

FIG. 1 is a structure schematic diagram of a semiconductor device in the prior art. As shown in FIG. 1, a semiconductor device includes a source 10, a gate 11 and a drain 12, and the gate 11 is located between the source 10 and the drain 12. Since the gate 11 of the semiconductor device is generally manufactured by photolithography process and the width of the gate 11 is very small, in photolithography, due to the existence of source 10 and drain 12, it is difficult for the developer to enter during development, and the gate 11 between the corners of the source and drain is easily distorted due to light diffraction, which causes the width of the gate 11 at the corners of the source and drain to be inconsistent with the width of the gate at other positions, resulting in unstable gate performance, thereby affecting the performance of the semiconductor device.

Based on the problem above, an embodiment of the present disclosure provides a semiconductor device, including an active region and a passive region surrounding the active region. The semiconductor device further includes a substrate, a multilayer semiconductor layer located on one side of the substrate, and a source, a gate and a drain located on one side of the multilayer semiconductor layer away from the substrate, the gate being located between the source and the drain, wherein, in a first direction, the gate includes, in turn, a first end portion, an intermediate portion and a second end portion, the intermediate portion, the source and the drain all being located in the active region, the first end portion and/or the second end portion extending into the passive region, and the first direction is parallel to the extension direction of the source, the gate and the drain, and in a second direction, an extension width of a portion at least located in the passive region of the first end portion and/or the second end portion is greater than an extension width of the intermediate portion, and the second direction is parallel to the direction in which the source points to the drain. Using the technical solution above, by setting the extension width of the first end portion and/or the second end portion at least located in the passive region to be greater, the first end portion and/or the second end portion of the gate having the greater extension width facilitates the penetration of the developer from at least one end portion to the intermediate portion, which reduces the development difficulty, and this can correct the distortion of the gate shape corresponding to the corner position at two ends of the source and drain due to light diffraction, significantly reduce the development difficulty, ensure that the gate shape corresponding to the corner position at two ends of the source and drain is the same or of slight difference with the shape of the intermediate portion, and ensure a stable gate structure and stable performance, which can further prevent distortion of the gate shape from affecting the power and frequency of the semiconductor device and ensure the performance of the semiconductor device is stable.

The above is the core conception of the present disclosure. The technical solutions in the embodiments of the present disclosure will be described clearly and completely in the following in conjunction with the accompanying drawings in the embodiments of the present disclosure. Based on the embodiments in the present disclosure, all other embodiments obtained by a person of ordinary skill in the art without making creative labor would fall within the protection scope of the present disclosure.

FIG. 2 is a structure schematic diagram of a semiconductor device provided by an embodiment of the present disclosure. As shown in FIG. 2, the semiconductor device 20 provided by the embodiment of the present disclosure includes an active region aa and a passive region bb surrounding the active region aa, the semiconductor device 20 further includes a substrate 221, a multilayer semiconductor layer 22 located on one side of the substrate 21, and a source 23, a gate 24 and a drain 25 located on one side of the multilayer semiconductor layer 22 away from the substrate 21, the gate 24 being located between the source 23 and the drain 25, wherein, in a first direction (X direction as shown), the gate 24 includes, in turn, a first end portion 241, an intermediate portion 242 and a second end portion 243, the intermediate portion 242, the source 23 and the drain 25 all being located in the active region aa, the first end portion 241 and/or the second end portion 243 extending into the passive region bb, and the first direction is parallel to the extension direction of the source 23, the gate 24 and the drain 25, and in a second direction (Y direction as shown), an extension width of a portion at least located in the passive region bb of the first end portion 241 and/or the second end portion 243 is greater than an extension width of the intermediate portion, and the second direction is parallel to the direction in which the source 23 points to the drain 25.

Exemplarily, as shown in FIG. 2, the source 23, the gate 24, and the drain 25 extend in a first direction and are arranged in a second direction, wherein both the source 23 and the drain 25 are located within the active region aa, and the gate 24 includes a portion within the active region aa and a portion located within the passive region bb. Specifically, in the first direction, the gate 24 includes, in turn, a first end portion 241, an intermediate portion 242, and a second end portion 243, wherein the intermediate portion 242 is located within the active region aa, and the first end portion 241 and/or the second end portion 243 are/is located within the passive region bb. FIG. 2 only takes an example in which the second end portion 243 is located in the passive region bb as for description. As shown in FIG. 2, an extension width of the second end portion 243 at least located in the passive region bb in the second direction is greater than an extension width of the intermediate portion 242 in the second direction; in this way, the second end portion located at least in the passive region bb has a greater extension width, and the second end portion of the gate having the greater extension width facilitates the penetration of the developer from the second end portion 243 to the intermediate portion 242, which reduces the development difficulty of the gate 24, and this can correct the distortion of the gate shape corresponding to the corner position at two ends of the source and drain due to light diffraction, significantly reduce the development difficulty, ensure that the gate shape corresponding to the corner position at two ends of the source and drain is the same or of slight difference with the shape of the intermediate portion 242, and ensure a stable structure and stable performance of the gate 24, which can further prevent distortion of the gate shape from affecting the power and frequency of the semiconductor device and ensure the performance of the semiconductor device is stable.

The material of substrate base 21 may be formed by one or more materials of silicon, sapphire, silicon carbide, gallium arsenide, gallium nitride, diamond, etc. It may also be other materials suitable for growing gallium nitride.

The multilayer semiconductor layer 22 is located on one side of the substrate 21, and the multilayer semiconductor layer 22 may specifically be a semiconductor material of group III-V compound, for instance, it may be formed from one or more of gallium arsenide, aluminum gallium arsenide, gallium nitride, aluminum gallium nitride, or indium gallium nitride.

It may be appreciated that in the second direction (Y direction as shown), the extension width of a portion of the first end portion 241 and/or the second end portion 243 at least located in the passive region bb is greater than the extension width of the intermediate portion 242, wherein the first end portion 241 and/or the second end portion 243 extending into the passive region bb may extend in the direction of the source 23 as shown in FIG. 2. It may also extend in the direction of the drain 25 (not shown). It may also extend in both the direction of the source 23 and the direction of the drain 25 (not shown). It is not limited in the embodiment of the present disclosure how to increase the width of the first end portion 241 and/or the second end portion 243 extending into the passive region bb, as long as it is sufficient to ensure that the extension width of the first end portion 241 and/or the second end portion 243 at least located in the passive region bb is greater than the extension width of the intermediate portion 242 and the gate corresponding to the corner position at two ends of the source and drain may be corrected.

It should be noted that the embodiment of the present disclosure is only described by taking the second end portion 243 extending into the passive region bb as an example. It may be appreciated that it is also possible to set the first end portion 241 to extend into the passive region bb, and it is also possible to set both the first end portion 241 and the second end portion 243 to extend into the passive region bb at the same time, which is not limited in the embodiment of the present disclosure. Further, when the first end portion 241 and the second end portion 243 extend into the passive region bb at the same time, shapes of the first end portion 241 and the second end portion 243 may be the same or different, which is also not limited in the embodiment of the present disclosure. It is sufficient to ensure that at least one end portion of the gate 24 extends into the passive region bb, and the width of the gates corresponding to the corner position at two ends of the source and drain is adjusted by the end portion of the gate extending into the passive region bb, the distortion of the gate shape corresponding to the corner position at two ends of the source and drain due to light diffraction is corrected, the gate stability is improved, the distortion of the gate shape is prevented from affecting the power and frequency of the semiconductor device, the stability of the semiconductor device is improved.

It should also be noted that the demarcation position between the first end portion 241 and the intermediate portion 242 and the demarcation position between the second end portion 243 and the intermediate portion 242 are not limited in the embodiment of the present disclosure; as for the end portion extending into the passive region bb, the start point of the end portion may be located in the active region aa or in the passive region bb, which is not limited in the embodiment of the present disclosure. For instance, taking FIG. 2 as an example, as for the second end portion 243 extending into the passive region bb, it may be appreciated that the position where the extension width of the second end portion 243 is changed in comparison with the extension width of the intermediate portion 242 serves as the start position of the second end portion 243; since the first end portion 241 is also located in the active region aa and the extension width of the first end portion 241 is the same as the extension width of the intermediate portion 242, therefore, in different cases, the demarcation position between the first end portion 241 and the intermediate portion 242 may be different, as long as it is sufficient to ensure that the first end portion 241 is located on one side of the intermediate portion 242 close to the passive region bb.

In summary, in the semiconductor device provided by the embodiment of the present disclosure, the first end portion and/or the second end portion of the gate extends into the passive region, and in the direction of the source pointing to the drain, the extension width of the portion of the first end portion and/or the second end portion at least located in the passive region is greater than the extension width of the intermediate portion. In this way, the first end portion and/or the second end portion located at least in the passive region has a greater extension width, and the first end portion and/or the second end portion of the gate having the greater extension width facilitates the penetration of the developer from at least one end portion to the intermediate portion, the development difficulty is reduced, which can correct the distortion of the gate shape corresponding to the corner position at two ends of the source and drain due to light diffraction, significantly reduce the development difficulty, ensure that the gate shape corresponding to the corner position at two ends of the source and drain is the same or of slight difference with the shape of the intermediate portion, and ensure a stable gate structure and stable performance, which can further prevent distortion of the gate shape from affecting the power and frequency of the semiconductor device and ensure the performance of the semiconductor device is stable.

Further, continuing referring to FIG. 2, in the second direction (Y direction as shown), the extension width of the first end portion 241 and/or the second end portion 243 extending into the passive region bb is L, and the extension width of the intermediate portion 242 is D, where 1.2*D≤L≤30*D.

Exemplarily, FIG. 2 takes an example in which the second end portion 243 extends into the passive region bb for description. Reasonably setting the extension width of the second end portion 243 extending into the passive region bb may ensure that the second end portion 243 extending into the passive region bb appropriately corrects the gate 24 corresponding to the corner position at two ends of the source and drain, and compensates or completely eliminates the problem of gate width reduction due to light diffraction; at the same time, this will not cause over-correction, and will not cause the problem of widening the width of the gate 24 at the corner of the source and drain due to over-correction, which ensures that the gate widths of the gates 24 in the active region aa are consistent or substantially the same, the structure of the gates 24 is stable, the performance of the gates 24 is stable, and further ensures that the performance of the semiconductor device is stable.

Further, through research, it is found that setting the extension width of the first end portion 241 and/or the second end portion 243 extending into the passive bb region being greater than L and the extension width D of the intermediate portion 242 and satisfying 1.2*D≤L≤30*D may ensure that appropriate correction is made to the gate 24 corresponding to the corner position at two ends of the source and drain, where L may be equal to 1.2*D, 1.5*D, 2*D, 3*D, 3.5*D, 5*D, 10*D, 15*D, or 30*D, and specific numerical values will be no longer enumerated in the embodiment of the present disclosure, and the specific correspondence of the extension width L of the first end portion 241 and/or the second end portion 243 extending into the passive region bb and the extension width D of the intermediate portion 242 will not be limited in the embodiment of the present disclosure, as long as it is sufficient to ensure that 1.2*D≤L≤30*D, and to ensure that the gate 24 corresponding to the corner position at two ends of the source and drain may be appropriately corrected.

The shape of the first end portion 241 and/or the second end portion 243 extending into the passive region bb may include at least one of a hammerhead shape, a circular shape, a semi-circular shape, a bulb shape, a rectangle shape, and an L shape, which is not limited in the embodiment of the present disclosure, as long as it is ensured that in the second direction (Y direction as shown), the extension width of the portion of the first end portion 241 and/or the second end portion 243 at least located in the passive region bb is greater than the extension width of the intermediate portion, the gate 24 corresponding to the corner position at two ends of the source and drain can be corrected, and the gate 24 has stable structure and stable performance. In the present disclosure, the first end portion 241 and/or the second end portion 243 extending into the passive region bb has an edge outline on at least one side close to the source 23 or the drain 25, the edge outline includes a first curve, and a circle center corresponding to an arc in which any two points of the first curve are located is on the same side of the first curve.

On the basis of the embodiments above, in the semiconductor device 20 provided by the embodiments of the present disclosure, the source 23 includes a first source corner 231 and a second source corner 232 located on one side close to the gate 24, and the first source corner 231 and/or the second source corner 232 are chamfers. The drain 25 includes a first drain corner 251 and a second drain corner 252 on one side close to the gate 24, and the first drain corner 251, and/or the second drain corner 252 are chamfers.

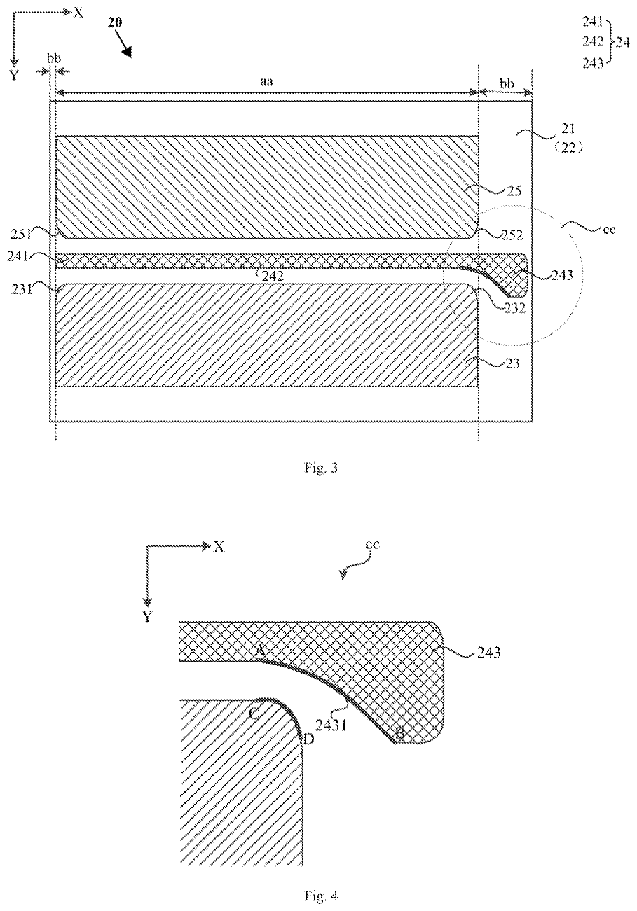

Exemplarily, FIG. 3 is a top view structure schematic diagram of a semiconductor device provided by an embodiment of the present disclosure. As shown in FIG. 3, in the semiconductor device 20, it is described by taking an example in which the first source corner 231, the second source corner 232, the first drain corner 251, and the second drain corner 252 are all arc-shaped chamfers. The first source corner 231, the second source corner 232, the first drain corner 251, and the second drain corner 252 are set as arc-shaped chamfers to ensure the first source corner 231, the second source corner 232, the first drain corner 251, and the second drain corner 252 smoothly transition at the corner positions. Compared with the right angle, the arc-shaped chamfer can not only reduce the diffraction intensity of light at the first source corner 231, the second source corner 232, the first drain corner 251, and the second drain corner 252, reduce the influence on the gate width of the gate due to light diffraction, and reduce the distortion of the gate shape corresponding to the corner position at two ends of the source and drain, but also avoid stress concentration, ensure stable structure and stable performance of the gate, and further ensure stable performance of the semiconductor device.

Further, when the first source corner 231 and/or the second source corner 232 are arc-shaped chamfers, and the first drain corner 251 and/or the second drain corner 252 are arc-shaped chamfers, a curvature radius of the arc-shaped chamfer may be 0.2-2 μm. Reasonable setting of the curvature radius of the arc-shaped chamfer, on the one hand ensures that the structural changes to the existing source 23 and the drain electrode 25 are small and the impact on the non-corner position is small, and on the other hand, it can also ensure that the size of the existing source 23 and the drain electrode 25 is matched, and the fabrication process of the chamfer is simple.

Further, continuing referring to FIG. 3, the first end portion 241 and/or the second end portion 243 extending into the passive region bb is bent toward one side of the source 23.

Exemplarily, in FIG. 3, the second end portion 243 extends into the passive region bb, and the second end portion 243 is bent toward one side of the source 23, so that the electric field peak between the gate and the source can be reduced.

Further, FIG. 4 is an enlarged structure schematic diagram of the cc region in FIG. 3. As shown in conjunction with FIGS. 3 and 4, the edge outline of the first end portion 241 and/or the second end portion 243 extending into the passive region bb on one side close to the source 23 includes a first curve, and a circle center corresponding to an arc in which any two points of the first curve are located is on the same side of the first curve. The first curve includes a first curve start point and a first curve end point. The source 23 includes a first source corner 231 and a second source corner 232 located on one side close to the gate 24, the first source corner 231, and/or the second source corner 232 are chamfers. The chamfer includes a chamfer start point and a chamfer end point. The first curve start point and the chamfer start point are located at the same position in the first direction, that is, the connecting line between the first curve start point and the chamfer start point is parallel to the second direction, and the first curve end point and the chamfer end point are located at the same position in the second direction, that is, the connecting line between the first curve end point and the chamfer end point is parallel to the first direction. In addition, the first curve start point may be further away from the intermediate portion in the first direction than the chamfer start point, and the first curve end point is further away from the gate in the second direction than the chamfer end point, that is, the first curve end point is located on one side of the chamfer end point away from the drain.

As shown in FIG. 4, the position where the extension width of the second end portion 243 changes is a first curve start point A of the first curve 2431, and the first curve start point A may serve as the start position of the second end portion 243. In the example shown in FIG. 4, the connecting line between the first curve start point A and the chamfer start point C of the source is parallel to the second direction, but, it can also be that the first curve start point A is further away from the intermediate portion in the first direction than the chamfer start point C, that is, the start position of the second end portion 243, compared with the chamfer start point C of the source, is further away from the intermediate portion in the first direction.

Exemplarily, FIGS. 3 and 4 only take an example in which the second end portion 243 extends into the passive region bb, and the second end portion 243 is bent toward one side of the source 23, and the edge outline of the second end portion 243 on one side close to the source 23 includes a first curve 2431 for description. Firstly, the first source corner 231 and the second source corner 232 are designed to be chamfers, compared with the right angle, the chamfer can reduce the diffraction intensity of light at the first source corner 231 and the second source corner 232, and reduce the influence on the gate width of the gate due to light diffraction. Further, the second end portion 243 is set to include a first curve 2431, and the circle center corresponding to an arc in which any two points of the first curve 2431 are located is on the same side of the first curve, and the first curve start point A of the first curve 2431 corresponds to the chamfer start point C, and the first curve end point B of the first curve 2431 corresponds to the chamfer end point D. In this way, the first curve edge of the second end portion 243 is opposite to the chamfer of the source corner, and the second end portion 243 starts to bend toward the source side from the corresponding position where the source chamfer begins to bend (that is, the second end portion 243 begins to bend when the source chamfer begins to bend). In this way, the electric field peak between the gate and the source caused by the corner of the source may be effectively alleviated. Further, the first curve start point A of the first curve 2431 corresponds to the chamfer start point C, which can be understood as the connecting line between the first curve start point A and the chamfer start point C is parallel to the second direction (Y direction as shown); the first curve end point B of the first curve 2431 corresponds to the chamfer end point D, which can be understood as the first curve end point B is located on one side of the chamfer end point D away from the drain 25, or the connecting line between the first curve end point B and the chamfer end point D is parallel to the first direction (X direction as shown), which ensures that the first curve 2431 completely envelops the source chamfer, and ensures that the electric field peak between the gate and the source caused by the source corner can be effectively alleviated.

Moreover, in the case where the first end portion 241 and/or the second end portion 243 extending into the passive region bb are bent toward one side of the drain 25, the edge outline on one side close to the drain 25 includes a first curve, the first curve includes a first curve start point and a first curve end point, the drain 25 includes a first drain corner and a second drain corner located on one side close to the gate 24, the first drain corner and/or the second drain corner are chamfers, and the chamfer includes a chamfer start point and a chamfer end point, the first curve start point is located at the same position or further away from the intermediate portion in the first direction compared to the chamfer start point, and the first curve end point is located at the same position or further away from the gate in the second direction compared to the chamfer end point. That is, the connecting line between the first curve start point and the chamfer start point is parallel to the second direction, or the first curve start point is further away from the intermediate portion in the first direction compared to the chamfer start point, and the connecting line between the first curve end point and the chamfer end point is parallel to the first direction, or the first curve end point is located on one side of the chamfer end point away from the source.

FIG. 5 is a top view structure schematic diagram of a gate provided by an embodiment of the present disclosure. As shown in conjunction with FIGS. 3, 4, and 5, the first curve 2431 includes a first point and a second point, and the second point is located on one side of the first point close to the passive region, a curvature radius corresponding to the second point is greater than a curvature radius corresponding to the first point.

Exemplarily, FIG. 5 takes an example in which the first point is the first curve start point A, and the second point is the first curve end point B for description. As shown in FIG. 5, the curvature radius R2 corresponding to the second point is greater than the curvature radius R1 corresponding to the first point. In this way, in the direction from the active region aa pointing to the passive region bb, the distance between the first curve 2341 and the source chamfer gradually increases, further optimizing the electric field between the gate 24 and the source 23.

Further, continuing referring to FIG. 5, the edge outline of the first end portion 241 and/or the second end portion 243 extending into the passive region bb on one side close to the source 23 includes a first curve, a circle center corresponding to an arc in which any two points of the first curve are located is on the same side of the first curve, and a curvature radius corresponding to any point in the first curve is greater than an extension width of the intermediate portion in the second direction, and the curvature radius corresponding to any point in the first curve is R, the extension width of the intermediate portion 242 in the second direction is D, and 1.5*D≤R≤20*D.

Exemplarily, FIG. 5 takes an example in which the second end portion 243 extends into the passive region bb, and the edge outline of the second end portion 243 close to the source 23 includes the first curve 2431, and any two points in the first curve 2431 are the first curve start point A and the first curve end point B for description. As shown in FIG. 5, the circle centers corresponding to the first curve start point A and the first curve end point B are both located on one side of the first curve 2431 close to the source 23, and the curvature radius corresponding to any point in the first curve 2431 is greater than the extension width D of the intermediate portion 242 in the second direction, which reduces the penetration difficulty of the developer from the end portion of the gate to the intermediate portion, reduces the display difficulty, ensures that the gate 24 corresponding to the corner position at two ends of the source and drain may be appropriately compensated, to compensate or completely eliminate the problem of gate width reduction due to light diffraction.

Further, after extensive verification by the inventors, setting the curvature radius R (e.g., R1 or R2) corresponding to any point in the first curve 2431 and the extension width D of the intermediate portion 242 in the second direction to satisfy 1.5*D≤R≤20*D, and reasonably setting the shape of the end portion of the gate 24 extending to one side of the source 23 side may appropriately increase the level of penetration of the developer from the end portion of the gate 24 to the intermediate portion 242 of the gate 24, appropriately reduce the display difficulty and ensure that the gate 24 corresponding to the corner position at two ends of the source and drain may be appropriately corrected, wherein, R can be equal to 1.5*D, 2*D, 5*D, 10*D, 15*D, or 20*D, and specific numerical values will not be enumerated in the embodiment of the present disclosure, and the specific correspondence between the curvature radius R corresponding to any point in the first curve 2431 and the extension width D of the intermediate portion 242 is not limited in the embodiment of the present disclosure, while it is sufficient to ensure that 1.5*D≤R≤20*D, and ensure that the gate 24 corresponding to the corner position at two ends of the source and drain can be appropriately corrected.

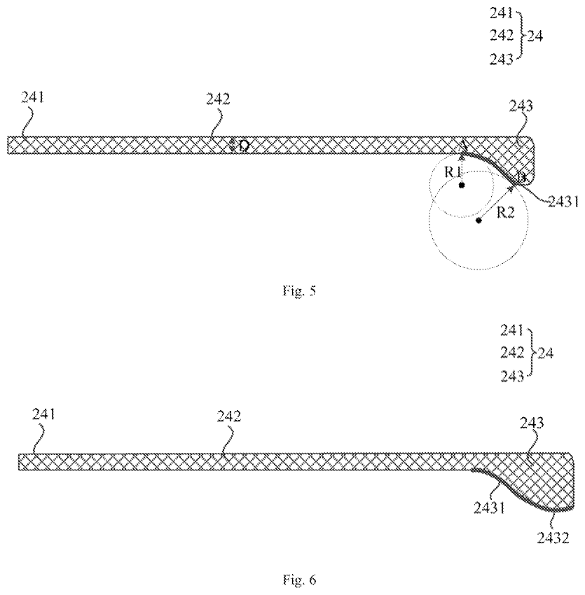

FIG. 6 is a top view structure schematic diagram of another gate provided by an embodiment of the present disclosure. As shown in FIG. 6, the edge outline of the first end portion 241 and/or the second end portion 243 extending into the passive region bb on at least one side close to the source 23 or the drain 25 further includes a second curve smoothly connected with the first curve, and the second curve is located on one side of the first curve close to the passive region bb. The circle center corresponding to the arc where any two points in the first curve are located and the circle center corresponding to the arc where any two points in the second curve are located are located on different sides of the edge outline, respectively.

Exemplarily, FIG. 6 only takes an example in which the second end portion 243 extends into the passive region bb and the second end portion 243 is bent toward one side of the source 23, and the edge outline of the second end portion 243 on one side close to the source 23 includes a first curve 2431 and a second curve 2432 that are smoothly connected for description. As shown in FIG. 6, the edge outline on one side of the second end portion 243 close to the source 23 is set to include a first curve 2431 and a second curve 2432 that are smoothly connected, to ensure that the edge outline of the second end portion 243 on one side close to the source 23 is a smooth curve, and no electric field peaks will be generated due to sharp corners on one side of the second end portion 243 close to the source 23, to ensure stable electrical properties of the semiconductor; at the same time, stress concentration may be avoided, and the mechanical properties of the semiconductor device may be ensured to be stable.

FIG. 7 is a cross-sectional structure schematic diagram of a semiconductor device provided by an embodiment of the present disclosure. As shown in FIG. 7, on the basis of the embodiments above, the semiconductor device 20 provided by the embodiments of the present disclosure may further include a field plate structure. Specifically, as shown in FIG. 7, the semiconductor device 20 may further include a field plate structure 26 located on one side of the gate 24 away from the substrate 21, and a plate capacitor is formed by the field plate structure 26 and the gate 24.

Exemplarily, since the extension width of the first end portion 241 and/or the second end portion 243 at least located in the passive region bb in the second direction is greater than the extension width of the intermediate portion 242 in the second direction, the overall area of the gate 24 is increased; since the gate 24 and the field plate structure 26 above the gate 24 form a plate capacitor, the gate 24 serves as a capacitor substrate of the plate capacitor, and increasing the area of the gate 24 may increase the capacitance of the plate capacitor, which can increase the control range of the gate and source capacitance, and further optimize the performance of the semiconductor device.

Further, continuing referring to FIG. 7, the semiconductor device 20 provided by the embodiment of the present disclosure may further include a protective layer 27, which is located on one side of the field plate structure 26 away from the substrate 21 for encapsulating and protecting the semiconductor device 20.

Further, continuing referring to FIG. 7, the multilayer semiconductor layer 22 provided by the embodiment of the present disclosure may specifically include a nucleation layer 221 on the substrate 10, a buffer layer 222 located on one side of the nucleation layer 221 away from the substrate 21, a channel layer 223 located on one side of the buffer layer 222 away from the nucleation layer 221, and a barrier layer 224 located on one side of the channel layer 223 away from the buffer layer 222, wherein a heterojunction structure is formed by the barrier layer 224 and the channel layer 223, and 2DEG is formed at the interface of the heterojunction.

Exemplarily, materials of the nucleation layer 221 and the buffer layer 222 may be nitrides, specifically GaN or AN or other nitrides, and the nucleation layer 221 and the buffer layer 222 may be used to match the material of the substrate base 10 and the epitaxial channel layer 223. Material of the channel layer 223 may be GaN or other semiconductor materials, such as InAlN. The barrier layer 224 is located above the channel layer 223, material of the barrier layer 224 may be any semiconductor material capable of forming a heterojunction structure with the channel layer 223, including a gallium compound semiconductor material or a nitride semiconductor material, such as InxAlyGazN1−x−y−z, where 0≤x≤1, 0≤y≤1, 0≤z≤1. A semiconductor heterojunction structure may be formed by the channel layer 223 and the barrier layer 224, and a high-concentration two-dimensional electron gas is formed at the interface between the channel layer 223 and the barrier layer 224.

The gallium nitride radio frequency device formed by using the semiconductor device structure of the present disclosure may improve the power and frequency of the gallium nitride radio frequency device on the premise of maintaining stable performance of the semiconductor device, and thus it is more suitable for the field of high-frequency 5G communication.

It should be appreciated that the embodiments of the present disclosure improve the output power of the semiconductor device from the perspective of the structure design of the semiconductor device. The semiconductor devices include but are not limited to: high-power gallium nitride High Electron Mobility Transistor (referred to as HEMT) working in high voltage and high current environment, Silicon-On-Insulator (referred to as SOI) structure transistors, gallium arsenide (GaAs)-based transistors and Metal-Oxide-Semiconductor Field-Effect Transistor (referred to as MOSFET), Metal-Semiconductor Field-Effect Transistor (referred to as MISFET), Double Heterojunction Field-Effect Transistor (referred to as DHFET), Junction Field-Effect Transistor (referred to as JFET), Metal-Semiconductor Field-Effect Transistor (referred to as MESFET), Metal-Semiconductor Heterojunction Field-Effect Transistor (referred to as MISHFET) or other field effect transistors.

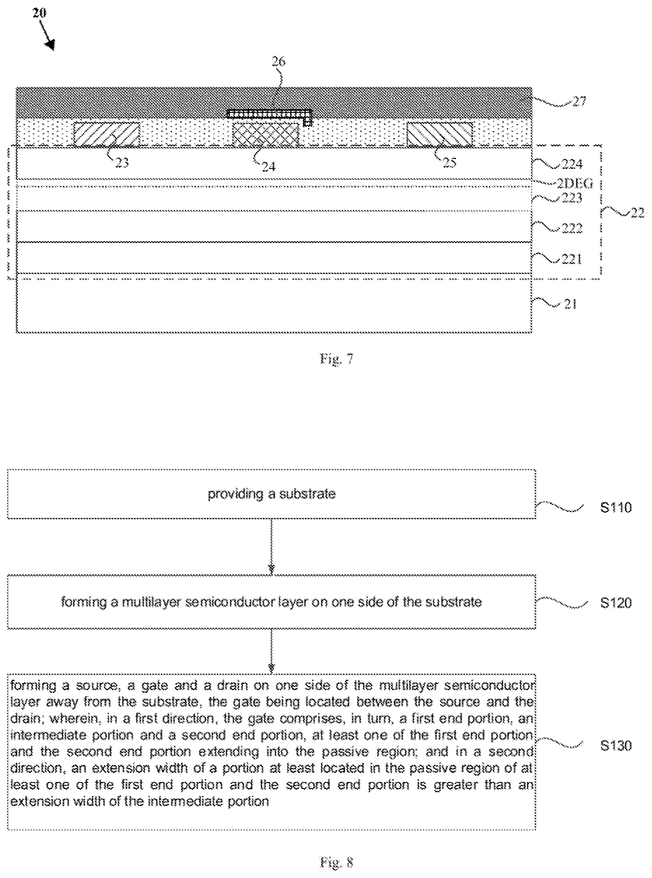

Based on the same inventive concept, embodiments of the present disclosure also provide a method of manufacturing a semiconductor device. FIG. 8 is a schematic flow diagram of a method of manufacturing a semiconductor device provided by an embodiment of the present disclosure. As shown in FIG. 8, the method of manufacturing a semiconductor device provided by the embodiment of the present disclosure may include:

S110, providing a substrate.

Exemplarily, material of the substrate may be Si, SiC, gallium nitride or sapphire, and may also be other materials suitable for growing gallium nitride. The method of forming the substrate may be atmospheric pressure chemical vapor deposition, sub-atmospheric pressure chemical vapor deposition, metal organic compound vapor deposition, low pressure chemical vapor deposition, high density plasma chemical vapor deposition, ultra high vacuum chemical vapor deposition, plasma enhanced chemical vapor deposition, catalyst chemical vapor deposition, hybrid physical chemical vapor deposition, rapid thermal chemical vapor deposition, vapor epitaxy, pulsed laser deposition, atomic layer epitaxy, molecular beam epitaxy, sputtering or evaporation.

S120, forming a multilayer semiconductor layer on one side of the substrate.

Exemplarily, the multilayer semiconductor layer is located on one side of the substrate, specifically, the multilayer semiconductor layer may be a group III-V compound semiconductor material, and 2DEG is formed in the multilayer semiconductor layer.

S130, forming a source, a gate and a drain on one side of the multilayer semiconductor layer away from the substrate, the gate being located between the source and the drain, wherein, in a first direction, the gate includes, in turn, a first end portion, an intermediate portion and a second end portion, the first end portion and/or the second end portion extending into the passive region, and in a second direction, an extension width of a portion at least located in the passive region of the first end portion and/or the second end portion is greater than an extension width of the intermediate portion.

Exemplarily, the first direction is parallel to the extending direction of the source, the gate and the drain, and the second direction is parallel to the direction in which the source points to the drain. In the first direction, the gate includes, in turn, the first end portion, the intermediate portion and the second end portion, the intermediate portion, the source and the drain all being located in the active region, at least one of the first end portion and the second end portion extending into the passive region, and the extension width of the first end portion and/or the second end portion at least located in the passive region in the second direction is greater than the extension width of the intermediate portion in the second direction; in this way, the first end portion and/or the second end portion of the gate with a greater extension width is conducive to the penetration of the developer from at least one end portion to the intermediate portion, which can correct the distortion of the gate shape corresponding to the corner position at two ends of the source and drain due to light diffraction, significantly reduce the development difficulty, ensure that the gate shape corresponding to the corner position at two ends of the source and drain is the same or of slight difference with the shape of the intermediate portion, and ensure a stable gate structure and stable performance, which can further prevent distortion of the gate shape from affecting the power and frequency of the semiconductor device and ensure the performance of the semiconductor device is stable.

In summary, in the method of manufacturing a semiconductor device provided by the embodiment of the present disclosure, by providing that the first end portion and/or the second end portion of the gate extends into the passive region, and in the direction of the source pointing to the drain, the extension width of the portion of the first end portion and/or the second end portion at least located in the passive region is greater than the extension width of the intermediate portion. In this way, the first end portion and/or the second end portion located at least in the passive region has a greater extension width, and the first end portion and/or the second end portion of the gate having the greater extension width facilitates the penetration of the developer from at least one end portion to the intermediate portion, which can correct the distortion of the gate shape corresponding to the corner position at two ends of the source and drain due to light diffraction, significantly reduce the development difficulty, ensure that the gate shape corresponding to the corner position at two ends of the source and drain is the same or of slight difference with the shape of the intermediate portion, and ensure a stable gate structure and stable performance, which can further prevent distortion of the gate shape from affecting the power and frequency of the semiconductor device and ensure the performance of the semiconductor device is stable.

It is to be noted that the foregoing embodiments are merely example embodiments of the present disclosure and technical principles used thereby. Those skilled in the art may understand that the present disclosure is not limited to the specific embodiments described herein, and those skilled in the art may make various obvious changes, readjustments, and substitutions without departing from the protection scope of the present disclosure. Therefore, although reference is made to the present disclosure in more detail in the foregoing embodiments, the present disclosure is not merely limited to the foregoing embodiments, other more equivalent embodiments may be further included without departing from the conception of the present disclosure, and the scope of the present disclosure depends on the scope of the appended claims.

1. A semiconductor device comprising an active region and a passive region surrounding the active region, the semiconductor device further comprising:
a substrate;
a multilayer semiconductor layer located on one side of the substrate; and
a source, a gate, and a drain located on one side of the multilayer semiconductor layer opposite the substrate, the gate located between the source and the drain;
wherein, in a first direction, the gate comprises, in turn, a first end portion, an intermediate portion, and a second end portion, the intermediate portion, the source, and the drain all located in the active region, at least one of the first end portion and the second end portion extending into the passive region, and the first direction is parallel to the extension direction of the source, the gate, and the drain; and
wherein, in a second direction, an extension width of a portion at least located in the passive region of at least one of the first end portion and the second end portion is greater than an extension width of the intermediate portion, and the second direction is parallel to the direction in which the source points to the drain.

2. The semiconductor device according to claim 1, wherein at least one of the first end portion and the second end portion extending into the passive region is bent toward one side of the source.

3. The semiconductor device according to claim 1, wherein i) an edge outline of at least one of the first end portion and the second end portion extending into the passive region on one side close to the source, or ii) the drain comprises a first curve, and a circle center corresponding to an arc in which any two points of the first curve are located is on the same side of the first curve.

4. The semiconductor device according to claim 3, wherein the first curve comprises a first point and a second point, wherein the second point is located on one side of the first point close to the passive region, and
wherein a curvature radius corresponding to the second point is greater than a curvature radius corresponding to the first point.

5. The semiconductor device according to claim 1, wherein
i) the source comprises a first source corner and a second source corner located on one side close to the gate, and at least one of the first source corner and the second source corner is a chamfer, or ii) the drain comprises a first drain corner and a second drain corner located on one side close to the gate, and at least one of the first drain corner and the second drain corner is a chamfer, the chamfer comprising a chamfer start point; and
wherein a start position of at least one of the first end portion and the second end portion is located at the same position or opposite the intermediate portion in the first direction compared to the chamfer start point.

6. The semiconductor device according to claim 3, wherein the first curve comprises a first curve start point and a first curve end point;
wherein i) the source comprises a first source corner and a second source corner located on one side close to the gate, and at least one of the first source corner and the second source corner is a chamfer, or ii) the drain comprises a first drain corner and a second drain corner located on one side close to the gate, and at least one of the first drain corner and the second drain corner is a chamfer; and the chamfer comprises a chamfer start point and a chamfer end point;
wherein the first curve start point is located at the same position or opposite the intermediate portion in the first direction compared to the chamfer start point; and
wherein the first curve end point is located at the same position or opposite the gate in the second direction compared to the chamfer end point.

7. The semiconductor device according to claim 3, wherein the edge outline further comprises a second curve smoothly connected to the first curve, the second curve located on one side of the first curve close to the passive region; and
wherein the circle centers corresponding to the arcs where any two points in the first curve and any two points in the second curve are located are located on different sides of the edge outline, respectively.

8. The semiconductor device according to claim 3, wherein a curvature radius corresponding to any point in the first curve is greater than an extension width of the intermediate portion in the second direction; and
wherein, a curvature radius corresponding to any point in the first curve is R, wherein the extension width of the intermediate portion in the second direction is D, and wherein 1.5*D≤R≤20*D.

9. The semiconductor device according to claim 1, wherein the semiconductor device further comprises a field plate structure located on one side of the gate opposite the multilayer semiconductor layer, and wherein a plate capacitor is formed by the field plate structure and the gate.

10. The semiconductor device according to claim 1, wherein shape of at least one of the first end portion and the second end portion extending into the passive region includes at least one of a hammerhead shape, a circular shape, a semi-circular shape, a bulb shape, a rectangle shape, and an L shape.

11. The semiconductor device according to claim 1, wherein in the second direction, the extension width of at least one of the first end portion and the second end portion extending into the passive region is L, wherein the extension width of the intermediate portion is D, and wherein 1.2*D≤L≤30*D.

12. A method of manufacturing a semiconductor device according to claim 1, the method comprising:
providing a substrate;
forming a multilayer semiconductor layer on one side of the substrate; and
forming a source, a gate, and a drain on one side of the multilayer semiconductor layer opposite the substrate, the gate located between the source and the drain;
wherein, in a first direction, the gate comprises, in turn, a first end portion, an intermediate portion and a second end portion, the intermediate portion, the source and the drain all located in the active region, at least one of the first end portion and the second end portion extending into the passive region, and the first direction is parallel to the extension direction of the source, the gate, and the drain; and
wherein in a second direction, an extension width of a portion at least located in the passive region of at least one of the first end portion and the second end portion of the passive region is greater than an extension width of the intermediate portion, and the second direction is parallel to the direction in which the source points to the drain.
